(19) United States
(12) Patent Application Publication
(10) Pub. No.: US 2015/0014795 A1
(43) Pub. Date: Jan. 15, 2015

(54) SURFACE PASSIVATION OF SUBSTRATE BY MECHANICALLY DAMAGING SURFACE LAYER

(71) Applicant: Avago Technologies General IP (Singapore) Pte. Ltd., Singapore (SG)

(72) Inventors: Martin FRANOSCH, Munich (DE); Andrew Thomas BARFKNECHT, Menlo Park, CA (US)

(21) Appl. No.: 13/938,742

(22) Filed: Jul. 10, 2013

(51) Int. Cl. H03H 9/17; H01L 21/768; H01L 21/67; H01L 21/304

(52) U.S. Cl. CPC H03H 9/171; H01L 21/304; H01L 21/768; H01L 21/67092
USPC 257/416; 438/667

(57) ABSTRACT

An apparatus comprises a substrate having a trap rich surface layer produced by mechanically grinding a surface of the substrate, an electrical contact disposed on the trap rich surface layer of the substrate, and an electronic device electrically connected to the electrical contact.

### BACKGROUND

In radio-frequency applications such as bulk acoustic wave (BAW) filters, surface acoustic wave (SAW) filters, and other passive and active devices, a high resistivity substrate is commonly used to achieve desired RF performance with high linearity. However, mobile charges at a surface of the substrate can lead to voltage dependent surface channels with reduced resistivity and capacitive coupling between pads or strip-lines, which leads to a nonlinear device.

The above substrate effects commonly result in intermodulation distortion (IMD), which is a nonlinear effect of two or more signals mixing within a device which produce undesirable higher order products. These unwanted signals may appear in the transmitting or receiving bands and contribute to the noise floor. For instance, if two or more signals are present at the input of such a non-linear device (e.g., a film bulk acoustic resonator (FBAR) Duplexer), the device may produce mixing products in the receive band of the duplexer.

To suppress the above substrate effects, some conventional devices are formed with a trap rich layer at the surface of the substrate. This potentially reduces carrier mobility and avoids, for instance, the creation of a metal-insulator-semiconductor (MIS) or metal-semiconductor device functioning as a voltage and frequency dependent capacitor.

Various methods have been proposed for making a trap rich layer. Examples of these methods include deposition of amorphous silicon, deposition of polycrystalline silicon, and amorphization of monocrystalline silicon (c-Si) with ion bombardment. Each of these methods, however, suffers from significant shortcomings. For instance, the deposition techniques tend to increase device cost, as they generally require deposition over the entire substrate, together with corresponding photo and etch steps. They also tend to increase a thermal budget of the device, which is especially undesirable at the end of processing. Similarly, ion implantation also tends to increase device cost, because of additional equipment required.

In view of the above and other shortcomings of conventional approaches, there is a general need for new techniques for addressing voltage dependent surface channels such as those that may affect performance in the context of RF applications.

### SUMMARY

In a representative embodiment, an apparatus comprises a substrate (e.g., a semiconductor substrate) having a trap rich surface layer produced by mechanically grinding a surface of the substrate, an electrical contact disposed on the trap rich surface layer of the substrate, and an electronic device electrically connected to the electrical contact. The electronic device may comprise, for instance, at least one FBAR. The apparatus may further comprise an insulating layer disposed between the trap rich surface layer and the electrical contact.

In certain embodiments, the apparatus further comprises a via extending through the substrate, wherein the electronic device is electrically connected to the electrical contact through the via. The substrate may form a lid over the electronic device, and the electronic device may be disposed on an additional substrate bonded to the substrate. In such embodiments, the apparatus may further comprise an additional trap rich surface layer produced by mechanically grinding a surface of the additional substrate, and an additional electrical contact disposed between the electronic device and the additional trap rich surface layer. Alternatively, the electronic device may be disposed on a first side of the substrate and the electrical contact may be disposed on a second side of the substrate opposite the first side, wherein the via extends between the first and second sides of the substrate. In such embodiments, the apparatus may further comprise an additional trap rich surface layer produced by mechanically grinding the first side of the substrate, and an additional electrical contact disposed between the electronic device and the additional trap rich surface layer.

In certain embodiments, the electronic device is disposed on the substrate over the electrical contact. In such embodiments, the apparatus may further comprise a lid formed over the electronic device, a via extending through the lid, and an additional electrical contact formed on the lid and electrically connected to the electrical contact through the via.

In certain embodiments, the substrate comprises at least one layer of monocrystalline silicon, and the trap rich surface layer comprises at least one layer of amorphous silicon, polycrystalline silicon, or dislocation rich silicon. In such embodiments, the trap rich surface layer may comprise a sub-layer comprising amorphous silicon, and the electrical contact may be disposed in contact with the amorphous silicon. Moreover, the trap rich surface layer may further comprise a sub-layer comprising dislocation rich silicon disposed below the sub-layer comprising amorphous silicon, and the trap rich surface layer may further comprise a sub-layer comprising polysilicon disposed between the sub-layer comprising dislocation rich silicon and the sub-layer comprising amorphous silicon.

In another representative embodiment, a method comprises mechanically grinding a surface of a substrate to produce a trap rich surface layer, and forming an electrical contact on the trap rich surface layer, wherein the electrical contact is electrically connected to an electronic device.

In certain embodiments, the method further comprises forming the electronic device on a first surface, and forming a via extending from the first surface to the surface of the substrate to facilitate electrical connection of the electrical contact to the electronic device through the via. In such embodiments, the first surface ma be located on a first side of the substrate, and the trap rich surface layer may be located on a second side of the substrate opposite the first side. Alternatively, the substrate may form a lid over the electronic device, and the first surface may be a surface of an additional substrate bonded to the substrate.

In certain embodiments, the substrate comprises monocrystalline silicon and the trap rich surface region comprises one or more layers each comprising one of amorphous silicon, polycrystalline silicon, and dislocation rich monocrystalline silicon. In certain embodiments, the electronic device is formed on an additional substrate, and the method further comprises bonding the substrate to the additional substrate to form a lid over the electronic device.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1A is a diagram of an apparatus comprising an electronic device formed on a substrate, a lid formed over the device, and vias formed through the lid, in accordance with a representative embodiment.

FIG. 1B is a diagram of an apparatus comprising an electronic device formed on a substrate, a lid formed over the device, and vias formed through the lid, in accordance with a representative embodiment.

FIG. 1C is a diagram of an apparatus comprising an electronic device formed on a substrate and vias formed through the substrate, in accordance with a representative embodiment.

FIG. 1D is a diagram of an apparatus comprising an electronic device formed on a substrate and vias formed through the substrate, in accordance with a representative embodiment.

FIG. 1E is a diagram of an apparatus comprising an electronic device formed on a substrate and electrical contacts formed on the substrate, in accordance with a representative embodiment.

FIG. 2 is a more detailed diagram of the apparatus of FIG. 1A, where the electronic device is an FBAR, in accordance with a representative embodiment.

FIG. 3 is a diagram illustrating an example of a trap rich surface layer in the lid shown in FIG. 1A, in accordance with a representative embodiment.

FIG. 4A is a flowchart illustrating a method of manufacturing the apparatus of FIG. 1A, in accordance with a representative embodiment.

FIG. 4B is a flowchart illustrating a method of manufacturing the apparatus of FIG. 1B, in accordance with a representative embodiment.

FIG. 4C is a flowchart illustrating a method of manufacturing the apparatus of FIG. 1C, in accordance with a representative embodiment.

FIG. 4D is a flowchart illustrating a method of manufacturing the apparatus of FIG. 1D, in accordance with a representative embodiment.

FIG. 4E is a flowchart illustrating a method of manufacturing the apparatus of FIG. 1E, in accordance with a representative embodiment.

FIG. 5 is a flowchart illustrating a more detailed example of the method of FIG. 4A, in accordance with a representative embodiment.

FIG. 6A is a diagram illustrating an operation in the method of FIG. 5, in accordance with a representative embodiment.

FIG. 6B is a diagram illustrating another operation in the method of FIG. 5, in accordance with a representative embodiment.

FIG. 6C is a diagram illustrating another operation in the method of FIG. 5, in accordance with a representative embodiment.

FIG. 6D is a diagram illustrating another operation in the method of FIG. 5, in accordance with a representative embodiment.

FIG. 6E is a diagram illustrating another operation in the method of FIG. 5, in accordance with a representative embodiment.

FIG. 7A is a graph illustrating a comparison of third-order IMD (IMD3) in a conventional apparatus and in an apparatus formed by the method of FIG. 5.

FIG. 7B is a diagram illustrating the generation of IMD3 in the context of measurements illustrated in FIG. 7A.

FIG. 7C is a diagram of an interdigital capacitor structure in an apparatus used to generate the measurements illustrated in FIG. 7A.

### DETAILED DESCRIPTION

In the following detailed description, for purposes of explanation and not limitation, example embodiments disclosing specific details are set forth in order to provide a thorough understanding of an embodiment according to the present teachings. However, it will be apparent to one having ordinary skill in the art having the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only, and is not intended to be limiting. The defined terms are in addition to the technical and scientific meanings of the defined terms as commonly understood and accepted in the technical field of the present teachings.

As used in the specification and appended claims, the terms ‘a’, ‘an’ and ‘the’ include both singular and plural referents, unless the context clearly dictates otherwise. Thus, for example, ‘a device’ includes one device and plural devices. As used in the specification and appended claims, and in addition to their ordinary meanings, the terms ‘substantial’ or ‘substantially’ mean to within acceptable limits or degree. As used in the specification and the appended claims and in addition to its ordinary meaning, the term ‘approximately’ means to within an acceptable limit or amount to one having ordinary skill in the art. For example, ‘approximately the same’ means that one of ordinary skill in the art would consider the items being compared to be the same

Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be below that element.

The described embodiments relate generally to methods and apparatuses in which an electronic device is formed on a substrate connected to frontside contacts, backside vias, or bonded lid vias. A trap rich layer is formed by mechanically grinding the substrate and/or the bonded lid in a region where electrical contacts are formed. For example, in certain embodiments an FBAR is formed on a substrate, and the substrate is bonded to a high resistivity lid wafer, which is then grinded to form a trap rich surface passivation layer on which electrical contacts are formed. The trap rich surface layer tends to reduce carrier mobility at the grinded surface of the lid wafer and suppress nonlinear substrate effects such as voltage and frequency dependent capacitances.

Certain details of FBARs and other devices that can be employed in various embodiments, including their methods of fabrication, are disclosed, for instance, in U.S. Pat. No. 7,728,485 to Handtmann et al., U.S. Pat. No. 6,107,721 to Lakin; U.S. Pat. Nos. 5,587,620, 5,873,153, 6,507,983, 6,384,697, 7,275,292 and 7,629,865 to Ruby et al.; U.S. Pat. No. 7,280,007 to Feng, et al.; U.S. Patent App. Pub. No. 2007/0205850 to Jamneala et al.; U.S. Pat. No. 7,388,454 to Ruby et al.; U.S. Patent App. Pub. No. 2010/0327697 to Choy et al.; U.S. Patent App. Pub. No. 2010/0327994 to Choy et al., U.S. patent application Ser. No. 13/658,024 to Nikkel et al.; U.S. patent application Ser. No. 13/663,449 to Burak et al.; U.S. patent application Ser. No. 13/660,941 to Burak et al.; U.S. patent application Ser. No. 13/654,718 to Burak et al.; U.S. Patent App. Pub. No. 2008/0258842 to Ruby et al.; and U.S. Pat. No. 6,548,943 to Kaitila et al. The disclosures of these patents and patent applications are specifically incorporated herein by reference. It is emphasized that the components, materials and method of fabrication described in these patents and patent applications are merely examples and other methods of fabrication and materials within the purview of one of ordinary skill in the art are contemplated. In addition, the devices disclosed in these patents and patent applications are merely examples, and other types of electronic devices can be employed in various embodiments described herein.

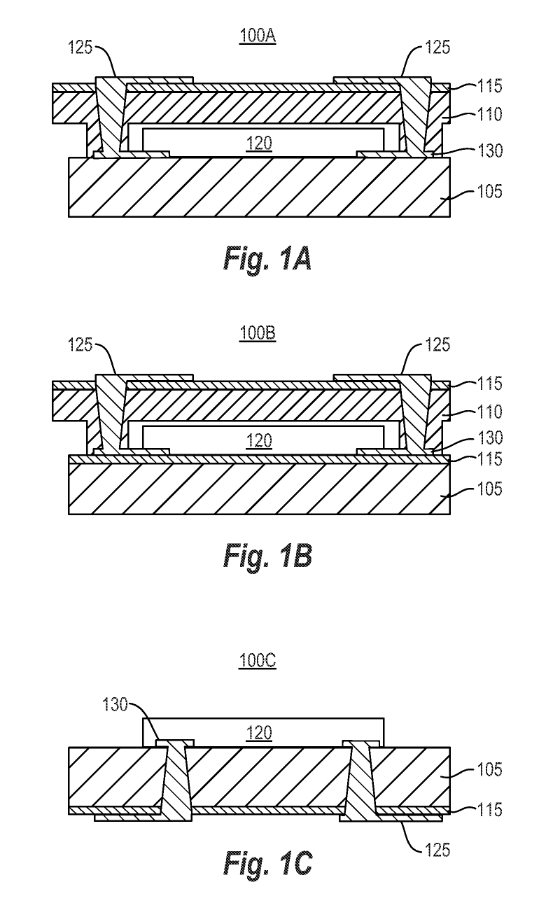

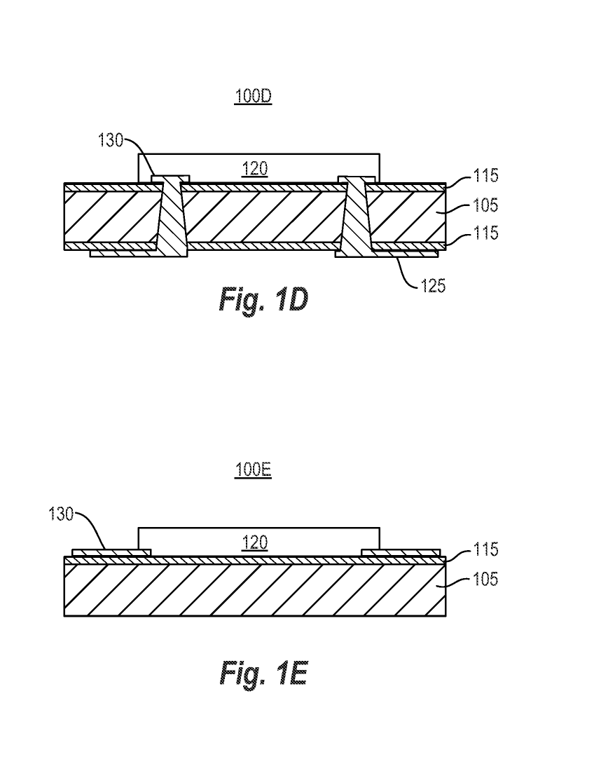

FIG. 1A is a diagram of an apparatus 100A comprising an electronic device formed on a substrate, a lid formed over the device, and vias formed through the lid, in accordance with a representative embodiment. FIG. 1B is a diagram of an apparatus 100B comprising an electronic device formed on a substrate, a lid formed over the device, and vias formed through the substrate, in accordance with a representative embodiment. FIG. 1C is a diagram of an apparatus 100C comprising an electronic device formed on a substrate and vias formed through the substrate, in accordance with a representative embodiment. FIG. 1D is a diagram of an apparatus 100D comprising an electronic device formed on a substrate and vias formed through the substrate, in accordance with a representative embodiment. FIG. 1E is a diagram of an apparatus 100E comprising an electronic device formed on a substrate and electrical contacts formed on the substrate, in accordance with a representative embodiment. In each of apparatuses 100A, 100B, 100C and 100D, mechanical grinding is performed on a high resistivity material through which the vias are formed, and then electrical contacts are formed on the mechanically grinded material. In apparatus 100E, electrical contacts are formed on the mechanically grinded material without vias. The mechanical grinding produces a trap rich surface layer, which tends to reduce carrier mobility and suppress nonlinear effects such as voltage and frequency dependent capacitances.

Referring to FIG. 1A apparatus 100A comprises a substrate 105, an electronic device 120 formed on substrate 105, a lid 110 bonded to substrate 105 over electronic device 120, and electrical contacts 125 formed on lid 110 and connected to electrical contacts 130 of electronic device 120 through vias in lid 110. Lid 110 has an upper surface with a trap rich surface layer 115. Although not shown in FIG. 1A, an insulating layer may be formed between trap rich surface layer 115 and electrical contacts 125 and/or between substrate 105 and electronic device 120 as well as electrical contacts 130. Such insulating layers may also be present in any of the embodiments illustrated in FIGS. 1B through 1E. Such layers, however, are not essential in any of these embodiments.

Substrate 105 and lid 110 are typically formed of a high resistivity semiconductor material, such as monocrystalline silicon or gallium arsenide (GaAs). This material typically takes the form of a wafer (e.g., a silicon wafer), so substrate 105 and lid 110 may also be referred to, respectively, as a device wafer and a lid wafer. Lid 110 can also be referred to as a microcap in some contexts.

Lid 110 forms an air cavity over electronic device 120, which can allow for unobstructed movement of an FBAR structure, for example. It can also hermetically seal electronic device 120 to prevent damage from environmental factors such as humidity. Where electronic device 120 does not comprise an acoustic resonator structure such as an FBAR, the air cavity may be unnecessary and can be omitted.

Trap rich surface layer 115 is typically formed by grinding the upper surface of lid 110 to form a zone which may comprise amorphous silicon, poly-silicon, and/or dislocation rich silicon. Of particular note, the zone may comprise any number of these different types of silicon in any sequence. The zone has relatively high concentration of electrical charge traps compared to other portions of lid 110 and substrate 105. Accordingly, it inhibits the mobility of charge carriers in lid 110, which limits their interference with the operation of electronic device 120, e.g., by preventing them from introducing nonlinear substrate effects such as voltage and frequency dependent capacitances.

The grinding is typically performed by applying a mechanical grinding wheel to the upper surface of lid 110 to create the zone of amorphous silicon, poly-silicon, and/or dislocation rich silicon up to some micron thickness. The thickness of the zone, as well as other characteristics of the grinded silicon may be adjusted by modifying a grit size of the grinding wheel or duration of the grinding process, for example. As an example, the grinding could be performed with the following parameters: grind wheel with grit size #2000, removal of about 20 μm of monocrystalline silicon.

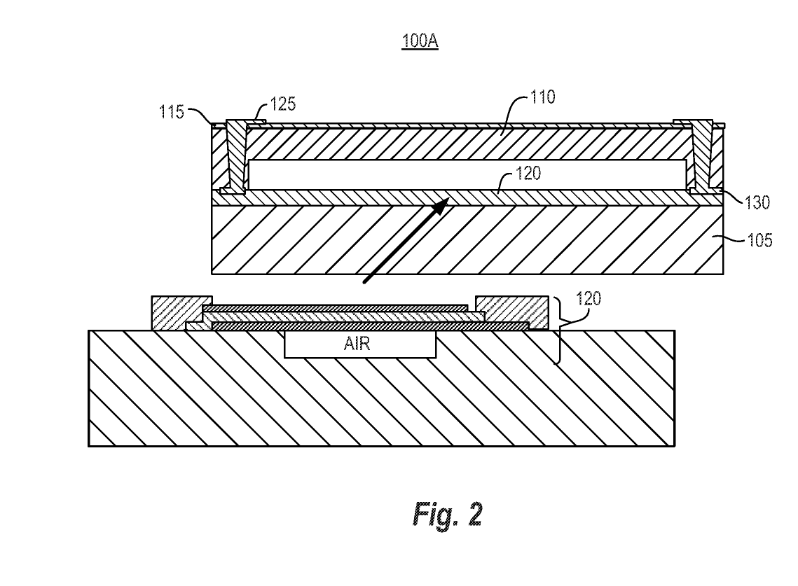

Electronic device 120 typically comprises an integrated circuit and/or acoustic resonator configured to process RF signals, although it is not limited to such devices. In certain examples, electronic device 120 comprises a filter comprising several acoustic resonators operating in combination. One example of such an acoustic resonator is shown in FIG. 2, which shows a single FBAR device. In general, the performance of electronic device 120 may benefit from the presence of trap rich surface layer 115 by avoiding electrical interference due to mobile carriers in lid 110. In RF applications, for instance, the performance of electronic device 120 may be improved by reducing IMD.

Electrical contacts 125 extend through the vias in lid 110 and are electrically connected to electrical contacts 130 of formed on substrate 105 and connected to electronic device 120. Electrical contacts 125 provide an input/output (IO) interface for electronic device 120 outside of lid 110.

Referring to FIG. 1B, apparatus 100B is substantially the same as apparatus 100A, except that an additional trap rich surface layer 115 is formed on substrate 105 below electrical contacts 130. The additional trap rich surface layer 115 has a similar structure and function compared to the trap rich surface layer 115 between substrate 105 and electrical contacts 125. In other words, it tends to reduce electrical interference due to mobile carriers in substrate 105. Additionally, the additional trap rich surface layer 115 of apparatus 100B can be formed by a process similar to that described above in relation to apparatus 100A.

Referring to FIG. 1C, apparatus 100C comprises electronic device 120 disposed on a top surface of substrate 105, trap rich surface layer 115 formed on a bottom surface of substrate 105, electrical contacts 125 formed on the bottom surface of substrate 105, and electrical contacts 130 formed between substrate 105 and electronic device 120. Electrical contacts 125 are connected to electronic device 120 through vias formed through substrate 105.

In the context of apparatus 100C, trap rich surface layer 115 has a structure similar to that described above in relation to apparatus 100A, and it performs a similar function as well. In other words, it tends to reduce electrical interference due to mobile carriers in substrate 105. Additionally, trap rich surface layer 115 of apparatus 100C can be formed by a process similar to that described above in relation to apparatus 100A.

Referring to FIG. 1D, apparatus 100D is substantially the same as apparatus 100C, except that it further comprises an additional trap rich surface layer 115 formed between substrate 105 and electrical contacts 130. The additional trap rich surface layer 115 has a similar structure and function compared to the trap rich surface layer 115 between substrate 105 and electrical contacts 125. In other words, it tends to reduce electrical interference due to mobile carriers in substrate 105. Additionally, the additional trap rich surface layer 115 of apparatus 100D can be formed by a process similar to that described above in relation to apparatus 100A.

Referring to FIG. 1E, apparatus 100E comprises trap rich surface layer 115 formed on the top surface of substrate 105, electrical contacts 130 formed on the top surface of substrate 105, and electronic device 120 disposed on the top surface of substrate 105 over electrical contacts 130. Electrical contacts 125 are connected to electronic device 120 through vias formed through substrate 105.

In the context of apparatus 100E, trap rich surface layer 115 has a structure similar to that described above in relation to apparatus 100A, and it performs a similar function as well. In other words, it tends to reduce electrical interference due to mobile carriers in substrate 105. Additionally, trap rich surface layer 115 of apparatus 100E can be formed by a process similar to that described above in relation to apparatus 100A.

FIG. 2 is a more detailed diagram of the apparatus of FIG. 1A, where electronic device 120 is an FBAR, in accordance with a representative embodiment.

Referring to FIG. 2, electronic device 120 comprises a piezoelectric layer disposed between lower and upper electrodes. An active region defined by an overlap between the piezoelectric layer and the lower and upper electrodes is suspended over an air cavity in substrate 105 to prevent acoustic vibrations in the active region from being absorbed by substrate 105. In alternative embodiments, the air cavity can be replaced by an acoustic reflector, such as a Bragg reflector, for instance.

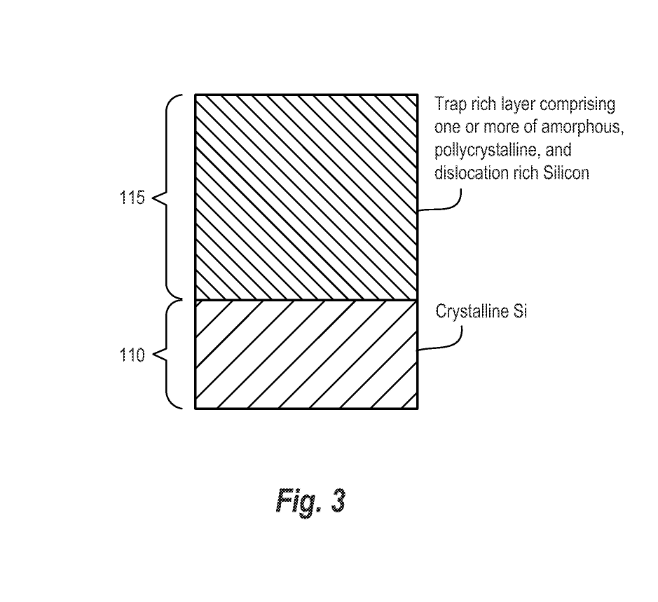

FIG. 3 is a diagram illustrating an example of trap rich surface layer 115 of FIGS. 1A-1E and 2, in accordance with a representative embodiment.

Referring to FIG. 3, trap rich surface layer 115 typically comprises one or more of amorphous silicon, poly-silicon, and dislocation rich silicon. It may comprise any number of these different types of silicon in any sequence or combination.

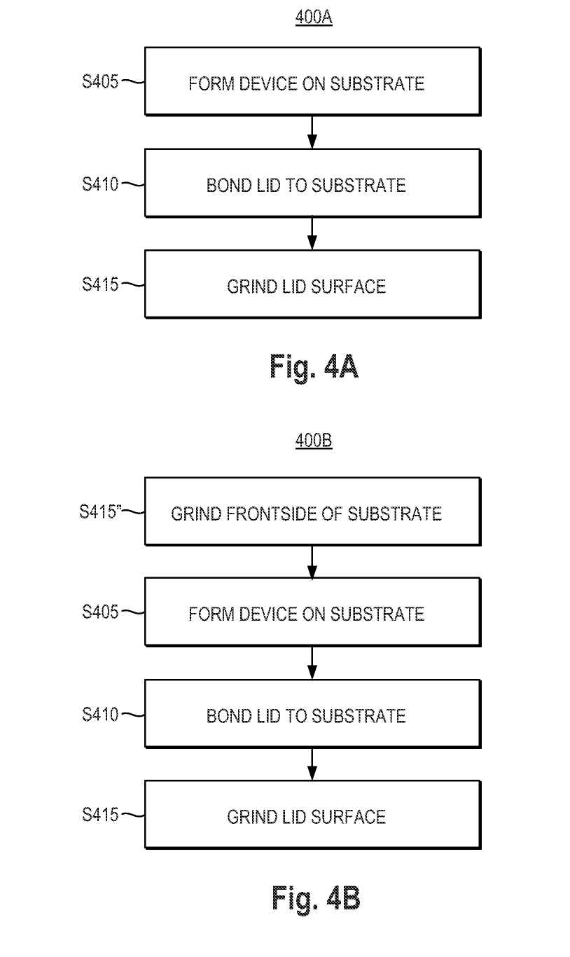

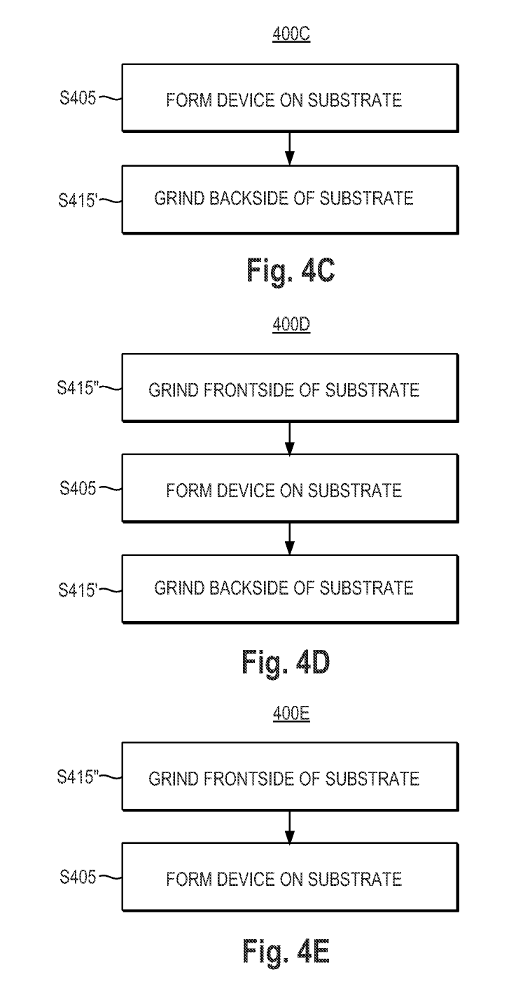

FIGS. 4A through 4E are flowcharts illustrating methods 400A-400E for manufacturing respective apparatuses 100A-100E of FIGS. 1A-1E, in accordance with various representative embodiments. Similar operations may be used for various parts of these methods, and a redundant description of those operations will be avoided for the sake of brevity. In the description that follows, example method operations are indicated by parentheses.

Referring to FIG. 4A, method 400A begins by forming electronic device 120 on substrate 105 (S405). Electronic device 120 can take various alternative forms and can be manufactured, for instance, by any of various processes described in the U.S. Patents and Patent Applications that have been incorporated by reference. The method further comprises bonding lid 110 onto substrate 105 over electronic device 120 (S410). The lid bonding can also be performed, for instance, using any of various processes described in the U.S. Patents and Patent Applications that have been incorporated by reference. The method still further comprises grinding an upper surface of lid 110 to produce trap rich surface layer 115 (S415). Thereafter, additional processes may be performed, such as forming electrical contacts 125 and/or other features. Moreover, the operations illustrated in FIG. 4A (as well as those illustrated in FIGS. 4B through 4E) are typically accompanied by additional preceding, succeeding, or intervening operations as required or desired for various alternative applications. As an example of an intervening operation, vias may be formed in lid 110 between operations S410 and S415 to allow subsequent formation of electrical contacts 125 through the vias.

Referring to FIG. 4B, method 400B is similar to method 400A, except that operation S405 is preceded by mechanical grinding of the frontside of substrate 105 (S415″). This grinding can be performed similar to operation S415, and the resulting additional trap rich surface layer 115 can perform a similar function to the trap rich surface layer formed by operation S415.

Referring to FIG. 4C, method 400C is similar to method 400A, except that operation S410 is omitted, and operation S415 is replaced by an operation S415′ in which trap rich surface layer 115 is formed on a backside of substrate 105 rather than on the upper surface of lid 110 through the mechanical grinding process. In conjunction with this method, vias can be formed through substrate 105, and electrical contacts 125 can be formed on trap rich surface layer 115 and connected to electronic device 120 through the vias.

Referring to FIG. 4D, method 400D is similar to method 400C, except that operation S405 is preceded by mechanical grinding of the frontside of substrate 105 (S415″). This grinding can be performed similar to operation S415, and the resulting additional trap rich surface layer 115 can perform a similar function to the trap rich surface layer formed by operation S415.

Referring to FIG. 4E, method 400E is similar to method 400D, except that it omits operation S415′. In addition, when used to form apparatus 100E, method 400E also omits various other operations that may be included in method 400D, such as the formation of vias and backside electrical contacts, for instance.

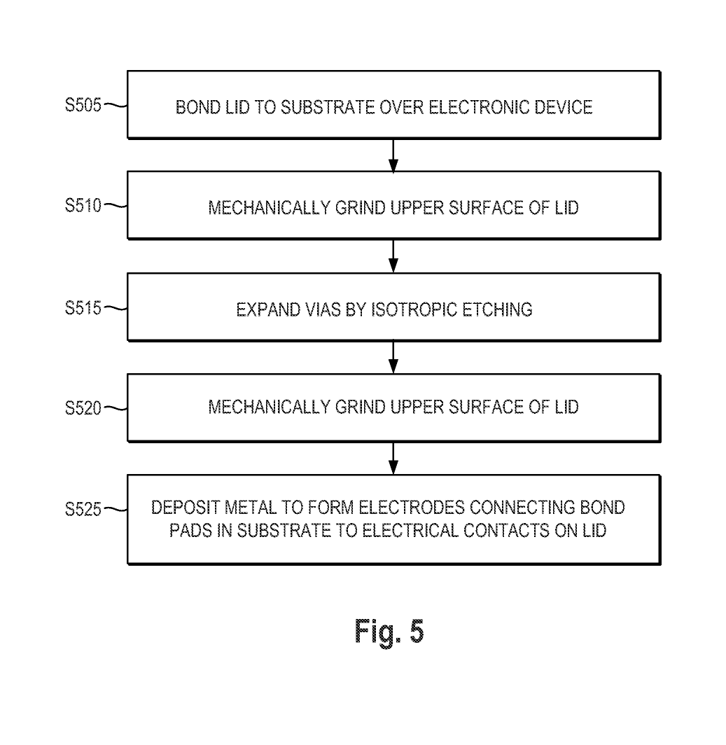

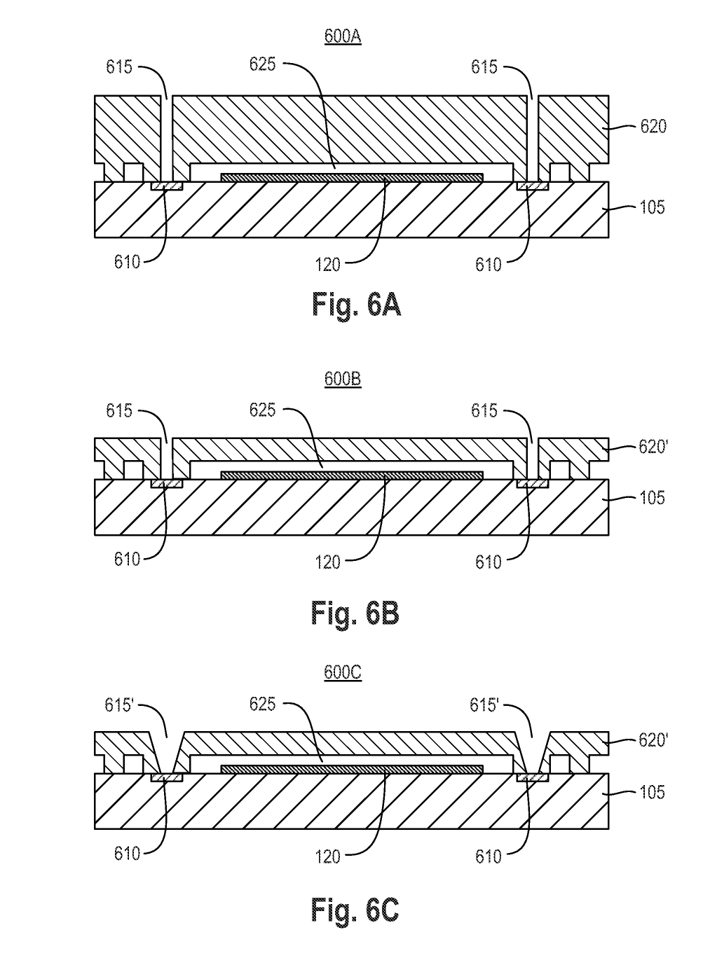

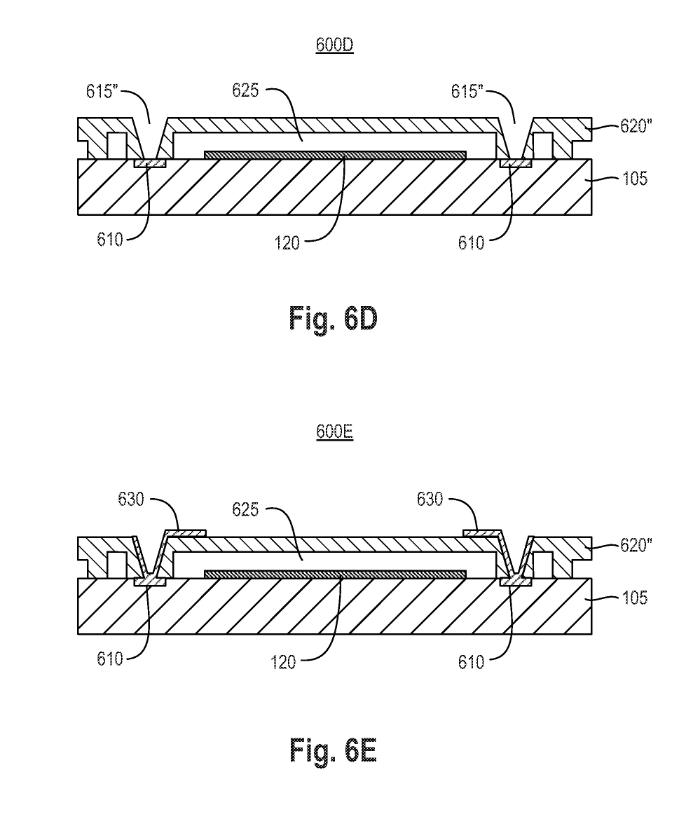

FIG. 5 is a flowchart illustrating a more detailed example of the method of FIG. 4A, in accordance with a representative embodiment, and FIGS. 6A through 6E are diagrams illustrating various operations performed in the method of FIG. 5. Although not specifically described herein, operations similar to some of those illustrated in FIGS. 5 and 6A through 6E can be used to form apparatus 100B, as will be apparent to those skilled in the art in view of this description. For instance, certain operations for expanding vias, as described below, can be applied to the formation of apparatus 100B.

Referring to FIGS. 5 and 6A through 6E, the method comprises connecting a lid to the substrate over the electronic device (S505). This is typically performed by a wafer bonding process. In the example of FIG. 6A, a result of operation S505 is illustrated by an apparatus 600A comprising a lid 620 connected to substrate 105 over electronic device 120. The connection of lid 620 over electronic device 120 creates an air gap 625 to allow free vibration of electronic device 120 in the event that it comprises an acoustic resonator. Vias 615 are formed in lid 620 to connect electrical contacts 610 with electrical contacts to be formed on lid 620.

The method further comprises performing a first mechanical grinding process on an upper surface of the lid connected to the substrate (S510). In the example of FIG. 6B, the first grinding process is illustrated by a reduction in the thickness of an upper portion of lid 620 and the relabeling of this feature as lid 620′.

The method further comprises performing an etching process to expand one or more vias connected between the surface of the substrate and the upper surface of the lid (S515). In the example of FIG. 6C, this entails widening vias 615 to produce vias 615′. In this example, the etching process is an isotropic etching process. Such an etching process can be performed using techniques within the purview of those skilled in the art. This etching process may remove trap rich portions of lid 620′ that have been created by the first mechanical grinding process. Accordingly, as indicated below, a second mechanical grinding process may be performed to produce a trap rich surface layer on lid 620′ prior to the formation of electrical contacts thereon.

The method further comprises performing the second mechanical grinding process on the upper surface of the lid connected to the substrate to produce an additional surface region having a relatively high concentration of electrical charge traps compared to other portions of the lid (S520). In the example of FIG. 6D, the second grinding process is illustrated by a reduction in the thickness of the upper portion of lid 620′ and the relabeling of this feature as lid 620″. The second mechanical grinding process may remove about 20 μm of silicon from lid 620′, for example.

Finally, the method comprises depositing a conductive material over the surface region to form one or more electrical contacts on the additional surface region and one or more electrical contacts connected to the substrate through the one or more vias, respectively (S525). In FIG. 6E, the deposition of this conductive material is indicated by the presence of electrical contacts 630 on lid 620″ and corresponding contact vias connecting electrical contacts 630 to electrical contacts 610.

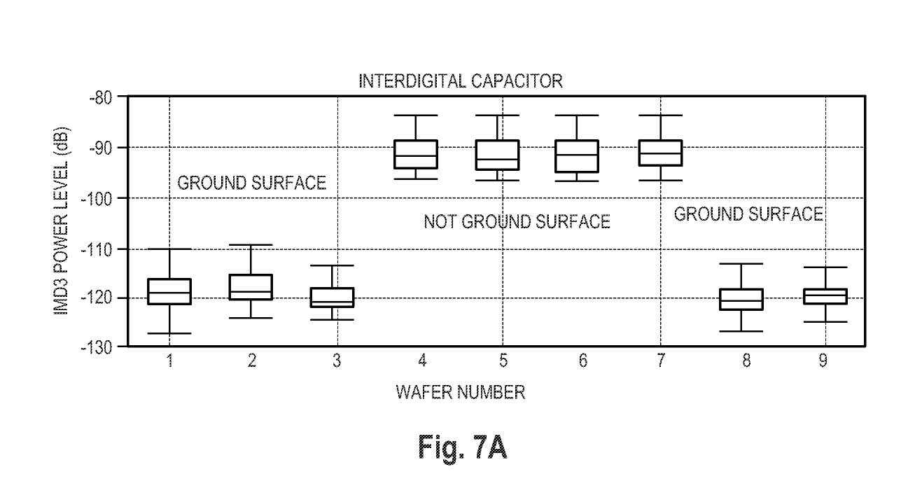

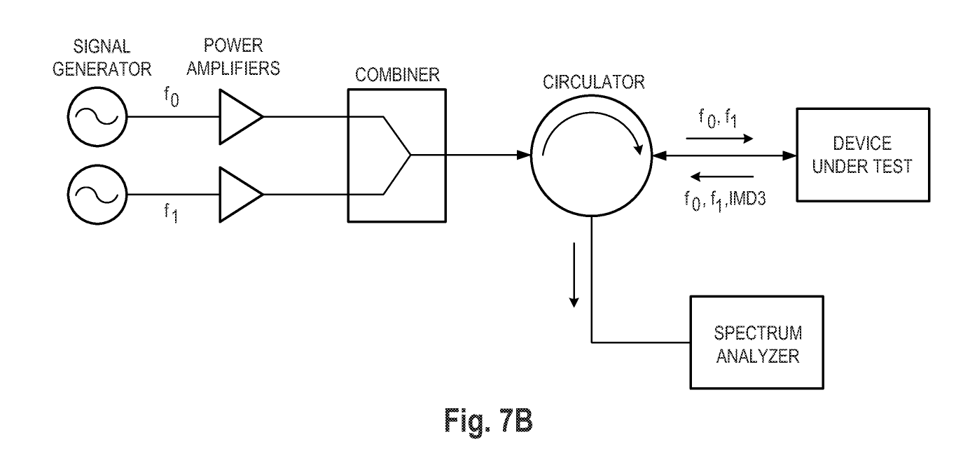

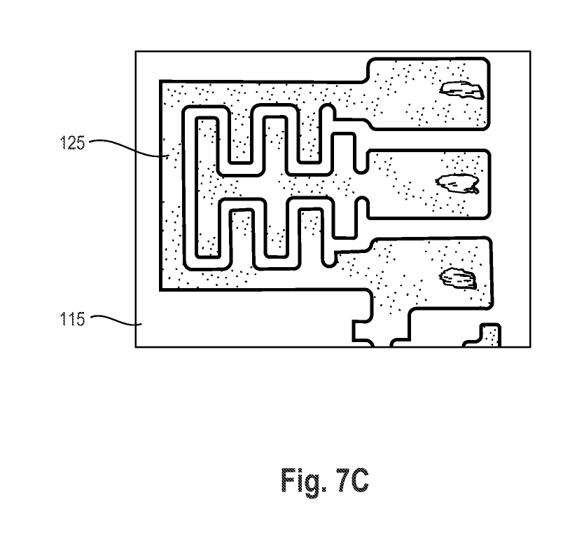

FIG. 7A is a graph illustrating a comparison of IMD3 in a conventional apparatus and in an apparatus formed by the method of FIG. 5. This graph was generated by performing measurements on four different instances of the conventional apparatus (labeled “wafers 4-7”) and five different instances of the apparatus formed by the method of FIG. 4 (labeled as wafers 1-3 and 8-10). FIG. 7B is a diagram illustrating the generation of IMD3 in the context of measurements illustrated in FIG. 7A. FIG. 7C is a diagram of an interdigital capacitor structure in an apparatus used to generate the measurements illustrated in FIG. 7A.

Referring to FIG. 7A, as an example of IMD the 3^{rd} order IMD (IMD3) power levels are tested on a simple inter digital capacitor structure. The conventional apparatus exhibits consistently higher levels of IMD3 compared to the apparatus formed by the method of FIG. 5. In particular, the conventional apparatus exhibits about 30 dB higher IMD3 power level. In general, the IMD3 signals can appear in the passband of a duplexer and can have undesired effects such as, for instance, jamming receiving sensitivity. Consequently, these IMD3 signals tend to raise the system floor, so the illustrated reduction in the IMD3 signals can provide benefits in system operation.

Referring to FIG. 7B, the measurements illustrated in FIG. 7A can be generated by stimulating a device under test (DUT) with at least two signals having different frequency components, such as the illustrated frequencies f₀ and f₁. Intermodulation of those frequency components produces IMD3 products, and the respective power levels of those products are then measured to produce the results shown in FIG. 7A.

Referring to FIG. 7C, IMD3 effects of trap rich surface layer 115 in the measurements of FIG. 7A can be evaluated by performing tests on electrical contacts 125 in the form of metal lines on lid 110 or substrate 105. Due to its shape, the structure shown in FIG. 7C is referred to as an interdigital capacitor structure, as also indicated by the label in FIG. 7A. In the context of FIGS. 7A, the IMD3 measurements represent nonlinear behavior of the substrate on which the metal lines are formed.

While example embodiments are disclosed herein, one of ordinary skill in the art appreciates that many variations that are in accordance with the present teachings are possible and remain within the scope of the appended claims. The embodiments therefore are not to be restricted except within the scope of the appended claims.

1. An apparatus, comprising:
a substrate having a trap rich surface layer produced by mechanically grinding a surface of the substrate;
an electrical contact disposed on the trap rich surface layer of the substrate; and
an electronic device electrically connected to the electrical contact.

2. The apparatus of claim 1, further comprising a via extending through the substrate, wherein the electronic device is electrically connected to the electrical contact through the via.

3. The apparatus of claim 2, wherein the substrate forms a lid over the electronic device, and the electronic device is disposed on an additional substrate bonded to the substrate.

4. The apparatus of claim 3, further comprising:
an additional trap rich surface layer produced by mechanically grinding a surface of the additional substrate; and
an additional electrical contact disposed between the electronic device and the additional trap rich surface layer.

5. The apparatus of claim 2, wherein the electronic device is disposed on a first side of the substrate and the electrical contact is disposed on a second side of the substrate opposite the first side, wherein the via extends between the first and second sides of the substrate.

6. The apparatus of claim 5, further comprising:
an additional trap rich surface layer produced by mechanically grinding the first side of the substrate; and
an additional electrical contact disposed between the electronic device and the additional trap rich surface layer.

7. The apparatus of claim 1, wherein the electronic device is disposed on the substrate over the electrical contact.

8. The apparatus of claim 7, further comprising a lid formed over the electronic device, a via extending through the lid, and an additional electrical contact formed on the lid and electrically connected to the electrical contact through the via.

9. The apparatus of claim 1, further comprising an insulating layer disposed between the trap rich surface layer and the electrical contact.

10. The apparatus of claim 1, wherein the substrate comprises at least one layer of monocrystalline silicon, and the trap rich surface layer comprises at least one layer of amorphous silicon, polycrystalline silicon, or dislocation rich silicon.

11. The apparatus of claim 10, wherein the trap rich surface layer comprises a sub-layer comprising amorphous silicon, and the electrical contact is disposed in contact with the amorpohous silicon.

12. The apparatus of claim 11, wherein the trap rich surface layer further comprises a sub-layer comprising dislocation rich silicon disposed below the sub-layer comprising amorphous silicon.

13. The apparatus of claim 12, wherein the trap rich surface layer further comprises a sub-layer comprising polysilicon disposed between the sub-layer comprising dislocation rich silicon and the sub-layer comprising amorphous silicon.

14. The apparatus of claim 1, wherein the electronic device comprises at least one film bulk acoustic resonator (FBAR).

15. A method, comprising:
mechanically grinding a surface of a substrate to produce a trap rich surface layer; and
forming an electrical contact on the trap rich surface layer, wherein the electrical contact is electrically connected to an electronic device.

16. The method of claim 15, further comprising:
forming the electronic device on a first surface; and
forming a via extending from the first surface to the surface of the substrate to facilitate electrical connection of the electrical contact to the electronic device through the via.

17. The method of claim 16, wherein the first surface is located on a first side of the substrate, and the trap rich surface layer is located on a second side of the substrate opposite the first side.

18. The method of claim 16, wherein the substrate forms a lid over the electronic device, and the first surface is a surface of an additional substrate bonded to the substrate.

19. The method of claim 15, wherein the substrate comprises monocrystalline silicon and the trap rich surface region comprises one or more layers each comprising one of amorphous silicon, polycrystalline silicon, and dislocation rich monocrystalline silicon.

20. The method of claim 15, wherein the electronic device is formed on an additional substrate, and the method further comprises bonding the substrate to the additional substrate to form a lid over the electronic device.
